(19) United States
(12) Patent Application Publication
(10) Pub. No.: US 2024/0150898 A1
(43) Pub. Date: May 9, 2024

(54) CHAMBER LINER FOR SUBSTRATE PROCESSING APPARATUS

(71) Applicant: ASM IP Holding B.V., Almere (NL)

(72) Inventors: Yoshiyuki Kikuchi, Tokyo (JP); Hirotsugu Sugiura, Tokyo (JP); Alexey Remnev, Kawasaki (JP); Koei Aida, Tokyo (JP); Lingjun Xue, Tokyo (JP)

(21) Appl. No.: 18/386,481

(22) Filed: Nov. 2, 2023

Related U.S. Application Data
(60) Provisional application No. 63/423,145, filed on Nov. 7, 2022.

(51) Int. Cl. C23C 16/458; H01J 37/32

(52) U.S. Cl. CPC C23C 16/4585; H01J 37/32715; H01J 37/32743; H01J 2237/3321; H01J 2237/3323

(57) ABSTRACT

A substrate processing apparatus is provided. A substrate processing apparatus comprises a reaction chamber provided with a chamber wall comprising a first sidewall, a second sidewall disposed opposite to the first sidewall, a bottom wall connected to the first sidewall and the second sidewall; a gate valve tunnel disposed in the first sidewall configured to be closed by a gate valve; a substrate support provided with a top plate and a shaft, the substrate support being disposed within the reaction chamber and configured to support a substrate on the top plate, wherein the substrate support is configured to be vertically movable between a process position and a transfer position; and a liner disposed around perimeter of the substrate support and configured to move with the substrate support, wherein an outer wall of the liner is configured to cover the gate valve tunnel when the substrate support is in the process position.

### CROSS-REFERENCE TO RELATED APPLICATIONS

This application claims priority to U.S. Provisional Patent Application Ser. No. 63/423,145 filed Nov. 7, 2022 titled CHAMBER LINER FOR SUBSTRATE PROCESSING APPARATUS, the disclosure of which is hereby incorporated by reference in its entirety.

### FIELD OF INVENTION

The present disclosure relates generally to a substrate processing apparatus and particularly a chamber liner, which facilitates a more uniform film deposition process across a surface within the reaction chamber, on a substrate.

### BACKGROUND OF THE DISCLOSURE

Integrated circuits comprise multiple layers of materials deposited by various techniques, including Chemical Vapor Deposition (CVD), Atomic Layer Deposition (ALD), Plasma Enhanced CVD (PECVD), and Plasma Enhanced ALD (PEALD). As such, the deposition of materials on a semiconductor substrate is a critical step in the process of producing integrated circuits.

It is important to perform uniform processing on the surface of the substrate, but the processing result often varies for various reasons, for example, temperature distribution, gate valve direction, and/or non-uniformity of electric field strength. Continuous improvement of on-substrate uniformity is desirable.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with exemplary embodiments of the disclosure, a substrate processing apparatus is provided. A substrate processing apparatus comprises a reaction chamber provided with a chamber wall comprising a first sidewall, a second sidewall disposed opposite to the first sidewall, a bottom wall connected to the first sidewall and the second sidewall; a gate valve tunnel disposed in the first sidewall configured to be closed by a gate valve; a substrate support provided with a top plate and a shaft, the substrate support being disposed within the reaction chamber and configured to support a substrate on the top plate, wherein the substrate support is configured to be vertically movable between a process position and a transfer position; and a liner disposed around perimeter of the substrate support and configured to move with the substrate support, wherein an outer wall of the liner is configured to cover the gate valve tunnel when the substrate support is in the process position.

In various embodiments, a top of the liner may align substantially with a top of the top plate.

In various embodiments, the liner may comprise at least one of: a ceramic material; or a ceramic coated material.

In various embodiments, the apparatus may further comprise a substrate transfer chamber connected to the reaction chamber via the gate valve; and a substrate transfer robot disposed within the substrate transfer chamber for transferring the substrate between the reaction chamber and the substrate transfer chamber through the gate valve tunnel.

In various embodiments, the apparatus may further comprise a gas supply unit disposed in the reaction chamber, the gas supply unit being configured to supply a gas to the substrate.

In various embodiments, the gas supply unit may comprise a showerhead provided with a plurality of holes for supplying gas to the substrate.

In various embodiments, the showerhead may be configured to face the substrate support.

In various embodiments, the apparatus may further comprise an RF generator electrically coupled to the showerhead, wherein the substrate support is electrically grounded.

In various embodiments, the substrate processing apparatus may comprise a plasma enhanced chemical vapor deposition apparatus.

In various embodiments, a method of processing a substrate may comprise: placing a substrate on a substrate support in a reaction chamber through a gate valve channel; moving the substrate support to a process position with a liner to cover the gate valve channel, wherein the substrate support is connected to the liner such that the liner moves concurrently with the substrate support; and forming a plasma in the reaction chamber by applying a RF power.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 is a schematic diagram of an apparatus for processing a substrate.

FIG. 2 is a schematic diagram of an exemplary reaction chamber.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

As used herein, the term “atomic layer deposition” (ALD) may refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) may refer to any process wherein a substrate is exposed to one or more volatile precursors, which react and/or decompose on a substrate surface to produce a desired deposition.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

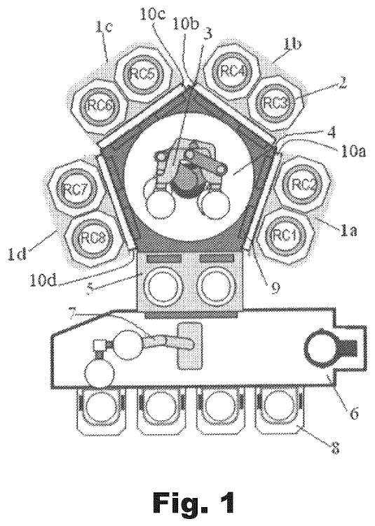

Reactor apparatus used for ALD, CVD, and/or the like, may be used for a variety of applications, including depositing and etching materials on a substrate surface. FIG. 1 is a schematic plan view of a substrate processing apparatus in an embodiment of the present invention. The substrate processing apparatus may comprise: (i) four process modules 1a, 1b, 1c, 1d, each having two reaction chambers; (ii) a substrate handling chamber (SHC) 4 including two back end robots 3 (substrate handling robots); and (iii) a load lock chamber (LLC) 5 for loading or unloading two substrates simultaneously, the load lock chamber 5 being attached to the one additional side of the substrate handling chamber 4, wherein each back end robot 3 is configured to be accessible to the load lock chamber 5. Each of the back end robots 3 have at least two end-effectors accessible to the two reaction chambers of each unit simultaneously, said substrate handling chamber 4 having a polygonal shape having four sides corresponding to and being attached to the four process modules 1a, 1b, 1c, 1d, respectively, and one additional side for a load lock chamber 4, all the sides being disposed on the same plane. The interior of each process modules 1a, 1b, 1c, 1d and the interior of the load lock chamber 5 may be isolated from the interior of the substrate handling chamber 4 by gate valves 9.

In some embodiments, a controller (not shown) may store software programmed to execute sequences of substrate transfer, for example. The controller may also: check the status of each process chamber; position substrates in each chamber and a cooling state 6 using sensing systems, control a gas box, and an electric box for each module; control a front-end robot 7 in an equipment front end module (EFEM) based on a distribution status of substrates stored in FOUP 8 and the load lock chamber 5; control the back end robots 3; and the control gate valves 9.

A skilled artisan may appreciate that the apparatus includes one or more controller(s) programmed or otherwise configured to cause the deposition and reactor cleaning processes described elsewhere herein to be conducted. The controller(s) may communicate with the various power sources, heating systems, pumps, robotics, gas flow controllers, or valves, as will be appreciated by the skilled artisan.

In FIG. 1, the apparatus is illustrated to have eight reaction chambers, but it may have 9 or more. In some embodiments, all the modules may have identical capabilities for processing substrates so that the unloading/loading can occur sequentially at regular intervals, thereby increasing productivity or throughput. In some embodiments, the modules may have different capabilities (e.g., different treatments) but their handling times may be substantially identical.

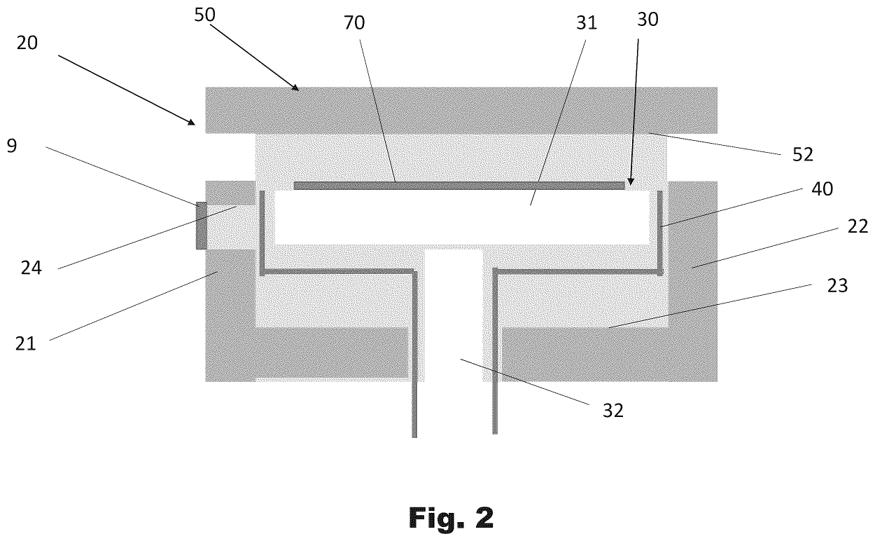

FIG. 2 is a schematic diagram of an exemplary reaction chamber. The substrate processing apparatus includes a reaction chamber 20 provided with a chamber wall comprising a first sidewall 21, a second sidewall 22 disposed opposite to the first sidewall 21, a bottom wall 23 connected to the first sidewall 21 and the second sidewall 22. A gate valve tunnel 24 is disposed in the first sidewall 21 and is configured to be closed by the gate valve 9. The substrate transfer robot 3 may transfer the substrate 70 between the reaction chamber 20 and the substrate transfer chamber 4 through the gate valve tunnel 24 when the gate valve 9 is opened.

The substrate processing apparatus further includes a substrate support 30 provided with a top plate 31 and a shaft 32. The substrate support 30 is disposed within the reaction chamber 20 and configured to support a substrate 70 on the top plate 31. The substrate support 30 may be configured to be vertically movable between a process position and a transfer position.

The substrate processing apparatus further includes a liner 40 disposed around perimeter of the substrate support 30. The substrate support 30 may be connected to the liner 40 such that the liner 40 moves concurrently with the substrate support 30. An outer wall of the liner 40 may be configured to cover the gate valve tunnel 24 when the substrate support is in the process position. Therefore, the process region is separated from the asymmetrical region, enhancing the gas flow, temperature and plasma uniformity in the processing region.

A top of the liner 40 may align substantially with a top of the top plate 31. Therefore, even if a particle is generated on the liner, the particle may not fall on the substrate 70. The liner 4 may comprise at least one of: a ceramic material; or a ceramic-coated material.

The substrate processing apparatus may further comprise a gas supply unit 50 disposed in the reaction chamber 20. The gas supply unit 50 may be configured to supply a gas to the substrate 70. The gas supply unit 50 may comprise a showerhead 52 provided with a plurality of holes for supplying gas to the substrate. The showerhead 52 may be configured to face the substrate support 30.

The substrate processing apparatus may comprise a plasma enhanced chemical vapor deposition apparatus. The substrate processing apparatus may further comprise an RF generator (not shown) electrically coupled to the showerhead 52. The substrate support 30 may be electrically grounded.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A substrate processing apparatus, comprising:
a reaction chamber provided with a chamber wall comprising a first sidewall, a second sidewall disposed opposite to the first sidewall, a bottom wall connected to the first sidewall and the second sidewall;
a gate valve tunnel disposed in the first sidewall configured to be closed by a gate valve;
a substrate support provided with a top plate and a shaft, the substrate support being disposed within the reaction chamber and configured to support a substrate on the top plate, wherein the substrate support is configured to be vertically movable between a process position and a transfer position; and
a liner disposed around perimeter of the substrate support and configured to move with the substrate support, wherein an outer wall of the liner is configured to cover the gate valve tunnel when the substrate support is in the process position.

2. The apparatus of claim 1, wherein a top of the liner aligns substantially with a top of the top plate.

3. The apparatus of claim 1, wherein the liner comprises at least one of: a ceramic material; or a ceramic coated material.

4. The apparatus of claim 1, further comprising a substrate transfer chamber connected to the reaction chamber via the gate valve; and
a substrate transfer robot disposed within the substrate transfer chamber for transferring the substrate between the reaction chamber and the substrate transfer chamber through the gate valve tunnel.

5. The apparatus of claim 1, further comprising a gas supply unit disposed in the reaction chamber, the gas supply unit being configured to supply a gas to the substrate.

6. The apparatus of claim 5, wherein the gas supply unit comprises a showerhead provided with a plurality of holes for supplying gas to the substrate.

7. The apparatus of claim 6, wherein the showerhead is configured to face the substrate support.

8. The apparatus of claim 7, further comprising an RF generator electrically coupled to the showerhead, wherein the substrate support is electrically grounded.

9. The apparatus of claim 1, wherein the substrate processing apparatus comprises a plasma enhanced chemical vapor deposition apparatus.

10. A method of processing a substrate; comprising:
placing a substrate on a substrate support in a reaction chamber through a gate valve channel;
moving the substrate support to a process position with a liner to cover the gate valve channel, wherein the substrate support is connected to the liner such that the liner moves concurrently with the substrate support; and
forming a plasma in the reaction chamber by applying a RF power.
